(19) United States
(12) Patent Application Publication
(10) Pub. No.: US 2005/0136684 A1
(43) Pub. Date: Jun. 23, 2005

(54) Gap-fill techniques

(75) Inventors: Kevin Mikio Mukai, Santa Clara, CA (US); Kimberly Branshaw, Santa Clara, CA (US); Zheng Yuan, Fremont, CA (US); Xinyun Xia, San Jose, CA (US); Xiaolin Chen, San Jose, CA (US); Dongqing Li, Santa Clara, CA (US); M. Ziaul Karim, San Jose, CA (US); Van Ton, San Jose, CA (US); Cary Ching, Sunnyvale, CA (US); Steve Ghanayeim, Los Altos, CA (US); Nitin K. Ingle, Campbell, CA (US)

Correspondence Address: Patent Counsel;Applied Materials, Inc., Legal Affairs Department, M/S 2061, P.O. Box 450A, Santa Clara, CA, 95052, US

(73) Assignee: APPLIED MATERIALS, INC., Santa Clara, CA (US)

(21) Appl. No.: 10/746,695

(22) Filed: Dec. 23, 2003

(51) Int. Cl. H01L 21/31; H01L 21/469

(52) U.S. Cl. 438/778; 438/788

(57) ABSTRACT

A variety of techniques may be employed, separately or in combination, to improve the gap-filling performance of a dielectric material formed by chemical vapor deposition (CVD). In one approach, a first dielectric layer is deposited using sub-atmospheric chemical vapor deposition (SACVD), followed by a second dielectric layer deposited by high density plasma chemical vapor deposition (HDP-CVD) or plasma-enhanced chemical vapor deposition (PECVD). In another approach, a SACVD dielectric layer is deposited in the presence of reactive ionic species flowed from a remote plasma chamber into the processing chamber, which performs etching during the deposition process. In still another approach, high aspect trenches may be filled utilizing SACVD in combination with oxide layers deposited at high temperatures.

### BACKGROUND OF THE INVENTION

One of the primary steps in the fabrication of modem semiconductor devices is the formation of a thin film on a semiconductor substrate by chemical reaction of gases. Such a deposition process is referred to as chemical vapor deposition or CVD. Conventional thermal CVD processes supply reactive gases to the substrate surface where heat-induced chemical reactions take place to produce a desired film. Plasma enhanced CVD techniques, on the other hand, promote excitation and/or dissociation of the reactant gases by the application of radio frequency (RF) energy to a reaction zone near the substrate surface, thereby creating a plasma. The high reactivity of the species in the plasma reduces the energy required for a chemical reaction to take place, and thus lowers the temperature required for such CVD processes as compared to conventional thermal CVD processes

CVD techniques may be used to deposit both conductive and insulative films during the fabrication of integrated circuits. For applications such as the deposition of insulation films for premetal or intermetal dielectric layers in an integrated circuit, one important physical property of the CVD film is its ability to completely fill gaps between adjacent structures without leaving voids within the gap. This property is referred to as the film's gap fill capability. Gaps that may require filling include spaces between adjacent raised structures such as transistor gates or conductive lines and etched trenches or the like

As semiconductor device geometries have decreased in size over the years, the aspect ratio of such gaps has dramatically increased. (Aspect ratio is defined as the height of the gap divided by the width of the gap). Gaps having a combination of a high aspect ratio and a small width present a challenge for semiconductor manufacturers to completely fill. In short, the challenge usually is to prevent the deposited film from growing in a manner that closes off the gap before it is filled

The semiconductor industry is continuously striving to develop new technologies and new film deposition chemistries to address challenges such as the gap fill issue. For example, several years ago some manufacturers switched from a silane-based chemistry for the deposition of intermetal dielectric silicon oxide layers to a TEOS-based (tetraethoxysilane) chemistry. This switch was at least in part due to the improved gap fill capability of the TEOS-based oxide layers. While a TEOS-based chemistry does indeed have improved gap fill capabilities, it too runs up against limitations when required to completely fill sufficiently high aspect ratio, small-width gaps

One process that the semiconductor industry has developed to improve the gap fill capability of a variety of different deposition processes, including TEOS-based silicon oxide deposition chemistries, is the use of a multistep deposition and etching process. Such a process is often referred to as a deposition/etch/deposition process.

Deposition/etch/deposition processes allocate filling of the space of a gap between two or more steps separated by a plasma etch step. The intervening plasma etch step removes material from the upper corners of the first deposited film more rapidly than sidewall portions of the film and lower portion of the gap, thereby enabling the subsequent deposition step to fill the gap without prematurely closure. Such deposition/etch/deposition processes can be performed in multiple chambers with separate chambers dedicated solely to either the deposition or etch steps. Alternatively, the deposition/etch/deposition processes may be performed utilizing a single chamber in an in-situ process.

Another approach developed to address the gap fill are high density plasma (HDP) processing CVD techniques. HDP-CVD techniques form a high density plasma at low vacuum pressures and introduce argon or another sputtering agent into the deposition process. The combination of deposition gases and sputtering agent result in a process that simultaneously deposits a film over the substrate and etches the growing film. For this reason, HDP-CVD techniques are sometimes referred to as simultaneous dep/etch processes. HDP-CVD processes generally have improved gap fill capabilities as compared to similar non-HDP-CVD processes.

As integrated circuit feature sizes some of the devices fabricated on the substrate become increasingly sensitive to damage that may be caused by plasma processing techniques including the dep/etch/dep and HDP-CVD techniques described above. This is particularly true as feature sizes are reduced to dimensions of 0.18 microns and less. Thus, some manufacturers attempt to avoid using plasma processing techniques on semiconductor substrates if at all possible.

In addition to depositing a desired film over the substrate, thermal CVD and plasma enhanced CVD deposition techniques typically leave unwanted deposition material on interior surfaces of the deposition chamber including the chamber walls. This unwanted deposition material may be removed with a chamber dry clean operation (also referred to as an in-situ clean operation). Such a dry clean operation is typically performed after the deposition operation is completed and the substrate is removed from the chamber. Etchant gases are then introduced into the chamber to remove the unwanted deposits. The dry clean operation can be a thermal etching process or more commonly a plasma etching process. It can also be done by flowing remotely dissociated etchant atoms into the chamber to etch the deposits. Such dry clean operations can be performed after a CVD film is deposited over a single or after n wafers. The actual frequency of the dry clean operation depends on a number of factors, including chemistry of the CVD process, length of the process, thickness of film deposited over the substrate, and deposition conditions, among other factors.

In view of the above problems with prior art gap fill deposition techniques, new and improved methods of filling gaps are desirable.

### BRIEF SUMMARY OF THE INVENTION

A variety of techniques may be employed, separately or in combination, to improve the gap-filling performance of a dielectric material formed by chemical vapor deposition (CVD). In one approach, a first dielectric layer is deposited using sub-atmospheric chemical vapor deposition (SACVD), followed by deposition of a second dielectric layer by plasma-assisted chemical vapor deposition techniques such as high density plasma chemical vapor deposition (HDP-CVD) or plasma-enhanced chemical vapor deposition (PECVD). In another approach, a dielectric layer is deposited using SACVD in the presence of reactive ionic species from a remotely generated plasma, which acts to perform etching during the deposition process. In still another approach, high aspect trenches may be filled utilizing SACVD in combination with subsequent high temperature deposition of oxide layers.

An embodiment of a gap-filling method in accordance with the present invention comprises disposing in a semiconductor processing chamber a semiconductor workpiece comprising a recessed feature. A first reaction is caused to occur in the processing chamber to deposit a first oxide layer within the first recessed feature at a pressure below 1 ATM, without applying RF energy to generate a plasma within the processing chamber. A second reaction is caused to occur to deposit a second oxide layer within the recess over the first oxide layer, by applying RF energy to generate a plasma.

An embodiment of a method of forming silicon oxide in accordance with the present invention comprises disposing a semiconductor workpiece comprising a recessed feature in a processing chamber at a pressure below 1 ATM. An oxygen-containing precursor gas is mixed with a silicon-containing precursor gas in the processing chamber to cause a reaction to deposit a silicon oxide layer within the recessed feature without applying RF energy to the processing chamber. A gas is disposed into a remote plasma chamber, and RF energy is applied to the remote plasma chamber to generate a reactive ion species. The reactive ion species is flowed into the processing chamber during mixing of the oxygen containing precursor gas and the silicon-containing precursor gas.

An alternate embodiment of a gap-filling method in accordance with the present invention comprises disposing in a semiconductor processing chamber, a semiconductor workpiece comprising a recessed feature. A first reaction in the processing chamber is caused to deposit a first oxide layer within the first recessed feature at a pressure below 1 ATM, without applying RF energy to generate a plasma within the processing chamber. A second reaction is caused to deposit a second oxide layer within the recess over the first oxide layer, by applying thermal energy to a silicon-containing precursor in the absence of a plasma.

A further understanding of the objects and advantages of the present invention can be made by way of reference to the ensuing detailed description taken in conjunction with the accompanying drawings.

### BRIEF DESCRIPTION OF THE DRAWINGS

FIG. 1A is a simplified representation of an exemplary CVD apparatus that can be used to practice the method of the present invention;

FIG. 1B is a simplified representation of one embodiment of a user interface for the exemplary CVD apparatus of FIG. 1A;

FIG. 1C is a block diagram of one embodiment of the hierarchical control structure of the system control software for the exemplary CVD apparatus of FIG. 1A;

FIGS. 2A-2B show simplified cross-sectional views showing the filling of a trench feature with oxide material utilizing conventional chemical vapor deposition techniques.

FIGS. 3A-3B show simplified cross-sectional views of filling of a trench feature with oxide material utilizing a gap-fill technique in accordance with one embodiment of the present invention.

### DESCRIPTION OF THE SPECIFIC EMBODIMENTS

A variety of techniques may be employed, separately or in combination, to improve the gap-filling performance of a dielectric material formed by chemical vapor deposition (CVD). In one approach, a first dielectric layer is deposited using sub-atmospheric chemical vapor deposition (SACVD), followed by deposition of a second dielectric layer by plasma-assisted deposition such as HDP-CVD or PECVD. In another approach, a dielectric layer is deposited using SACVD in the presence of reactive ionic species from a remotely generated plasma, which acts to perform etching during the deposition process. In still another approach, high aspect trenches may be filled utilizing SACVD in combination with high temperature deposition of oxide layers.

I. Gap Fill Techniques

As device geometries shrink, void-free filling of high aspect ratio spaces becomes increasingly difficult due to limitations of existing deposition processes. High density plasma CVD of silicon dioxide is conventionally employed for gap filling of trenches exhibiting large aspect ratios (i.e. >6:1).

Typical plasma-assisted chemical vapor deposition processes use gas mixtures comprising oxygen, hydrogen, silane, and fluorinated carbon compounds CₓF_{y} to provide a source for the deposited silicon oxide. Plasma-assisted processes may also employ gas mixtures comprising noble gases such as argon or helium in order to achieve sputtering effects concurrent with the deposition process. Due to the concurrent sputtering of materials from sidewall and gap opening, more material is deposited at the bottom of a high aspect ratio structures during HDP-CVD processes.

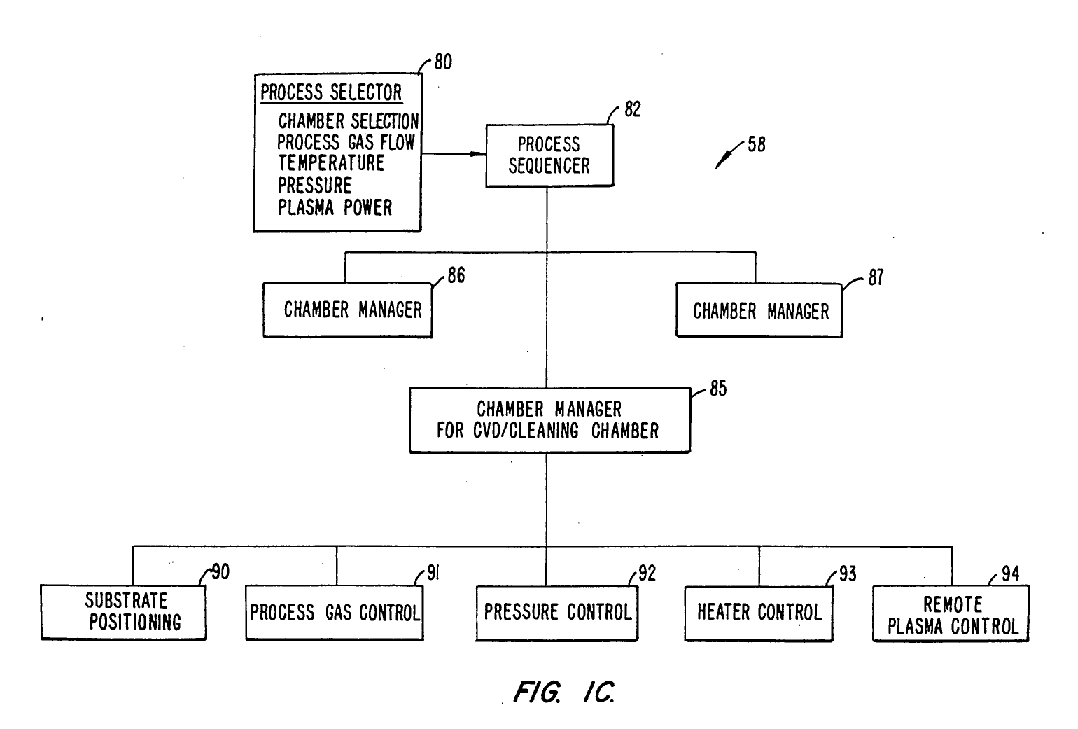

For aggressive (i.e. high aspect ratio) trench structures, redeposition or cusping may occur at the opening of the gap to be filled. FIG. 2A shows a simplified cross-sectional view of a trench feature 200 being filled with dielectric material 202 where cusp features 204 have formed. FIG. 2B shows a simplified cross-sectional view of the trench feature of FIG. 2A at a later point in the deposition process, wherein cusp features 204 have converged to create void 206. Because the HDP-CVD reactants cannot gain access to buried void 206, it will remain unfilled and can adversely affect the physical and/or electrical properties of the filled trench feature.

Cusping generally results from the angled directionality of neutral species in the HDP reactor that participate in sputtering/redeposition processes. Redeposition occurs due to sputtering of once-deposited dielectric material by directionally-charged species from Ar, He, or O₂ gases that fall to the trench bottom. Cusping occurs due to sputtered dielectric being redeposited on opposing surfaces through line-of-sight redeposition. These undesirable redeposition/cusping processes are enhanced as the width of the gap to be filled decreases and the corresponding aspect ratio increases.

In accordance with one embodiment of the present invention, a combination of sub-atmospheric chemical vapor deposition (SACVD) and high density plasma-assisted chemical vapor deposition processes may be employed to fill gaps having high aspect ratios. These embodiments employ a variety of SACVD and HDP-CVD approaches in different combinations to effectively fill gaps having high (>6:1) aspect ratios with insulating layers.

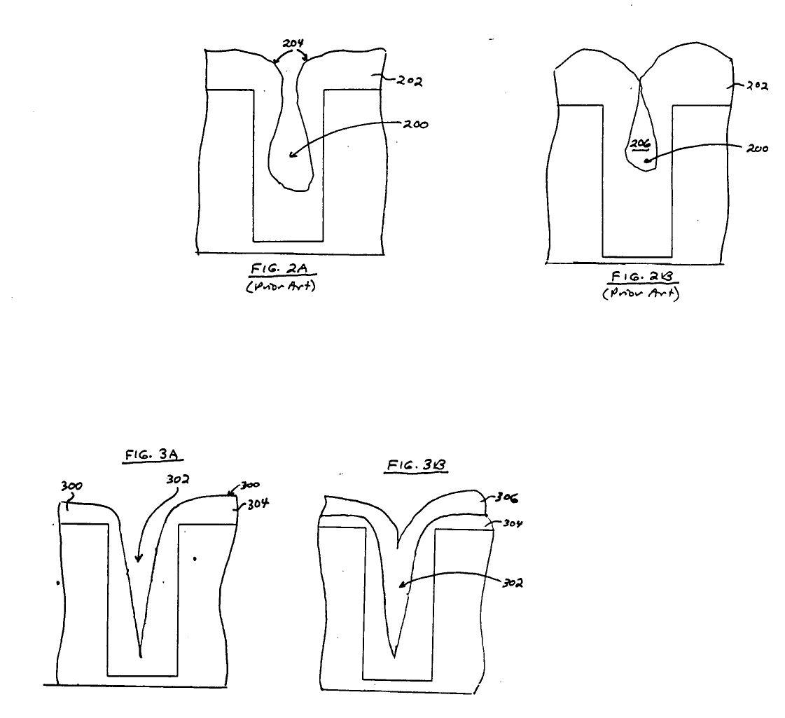

FIGS. 3A-3B show cross-sectional views of one embodiment of a gap-fill process in accordance with the present invention. In the first step shown in FIG. 3A, silicon oxide 300 is deposited within trench 302 at sub-atmospheric pressures without the application of RF power to the chamber during the deposition process. As a result of deposition of silicon oxide under these SACVD conditions, conformal silicon oxide layer 304 is formed within trench 302.

In the second step shown in FIG. 3B, a second silicon oxide layer 306 is formed within trench 302 over the conformal silicon oxide layer 304 as RF power is applied to the processing chamber to create a high density plasma. The silicon oxide material deposited during this second, HDP-CVD step ultimately fills the volume of trench 302 that remained unfilled after the initial SACVD step shown in FIG. 3A.

The SACVD component of techniques utilized in accordance with embodiments of the present invention combines desirable flow-like and conformal step coverage properties of ozone-TEOS deposition processes. Particular processes for SACVD of silicon oxide may utilize vaporized tetraethyl orthosilicate (TEOS) at a flow rate of between about 0-7000 mgm, and ozone gas having between about 1-25 wt. %. The SACVD of gap fill processes in accordance with embodiments of the present invention may occur within a temperature range of between about 100-700° C., at pressures between about 10-760 Torr.

The SACVD component of gap-filling processes in accordance with embodiments of the present invention may or may not be followed by a separate additional annealing step. This separate annealing step may be performed at temperatures of 400-1100° C. in ambients comprising H₂, He, steam, NₓO_{y}, and forming gas, for periods of up to about 5-6 hours. The anneal step may serve to densify the film by removing carbon and other impurities, and may also serve to heal structural imperfections such as seams by promoting the formation of SiO bonds within the film.

The plasma-assisted component of techniques utilized in accordance with embodiments of the present invention may include single or multi-step processes utilizing gases including but not limited to NF₃, SiF₄, SiH₄, Ar, He, or H₂ based processes. Such multi-step plasma-assisted processes include deposition/etch/deposition processes and deposition/sputter/deposition processes. The HDP-CVD of silicon oxide may be conducted in the temperature range of from between about 200-900° C. Gas flow rates range from between about 1-200 sccm for SiH₄, between about 1-1000 sccm for O₂, and between about 1-2000 sccm for Ar, He, or H₂ combined.

The basic multi-step deposition process outlined above in connection with FIGS. 3A-B may be varied in a number of ways. For example, in accordance with one alternative embodiment of the present invention, reactive ionic species may be generated remote from the processing chamber and then flowed to the processing chamber during the plasma-assisted CVD step. These reactive ionic species may comprise fluorine radicals generated by the application of RF power to fluorine-containing gases including, but not limited to, F₂, NF₃, C₂F₆, and C₃F₈. Once remotely generated, these active ionic species may be introduced into the processing chamber during the SACVD process to produce some etching of deposited material, thereby ensuring continued access by CVD reactants to regions within the recessed feature, and hence voidless deposition of material therein.

In accordance with another alternative embodiment of the present invention, a high temperature oxide (HTO) deposition step, rather than a plasma-assisted deposition step, may be performed following the SACVD deposition. The HTO deposition in accordance with embodiments of the present invention can occur at pressures up to 760 Torr and at temperatures of between about 600-1000° C. The high temperature oxide deposition may occur utilizing a silicon-containing precursor undergoing decomposition promoted by solely the application of thermal energy, or may occur utilizing a silicon-containing precursor in combination with a gas other than ozone.

In accordance with yet another alternative embodiment of the present invention, one or both of the SACVD and the subsequent deposition steps may be performed as a deposition/etch/deposition sequence. In certain embodiments, this intervening etch step may take the form of a predominantly physical-type (anisotropic) sputtering process, rather than a predominantly chemical-type (isotropic) etching process.

The gap filling techniques described above in accordance with embodiments of the present invention are useful for a number of different semiconductor processing applications. In one application, the gap fill techniques of the present invention may be employed in shallow trench isolation (STI) schemes to deposit dielectric material within shallow trenches formed in the surface of a semiconductor workpiece, and thereby provide electrical isolation between discrete active electrical devices formed thereon. In another application, the gap fill techniques of the present invention may be employed in premetal dielectric (PMD) schemes to deposit a planar dielectric layer within the topography resulting from fabrication of active electrical devices on the surface of a semiconductor workpiece.

The gap filling techniques described above in accordance with embodiments of the present invention also offer a number of favorable properties. For example, dielectric material deposited in accordance with embodiments of the present invention can fill trenches having a depth of between about 10 and 90 nm, at any pitch and having aspect ratios of up to about 20:1. Moreover, the dielectric material deposited in accordance with embodiments of the present invention is substantially free of voids and seams. In addition, the filled trench structures are compatible with chemical mechanical planarization (CMP) techniques that may subsequently be utilized to remove excess deposited material formed outside the trench.

II. Exemplary Processing System

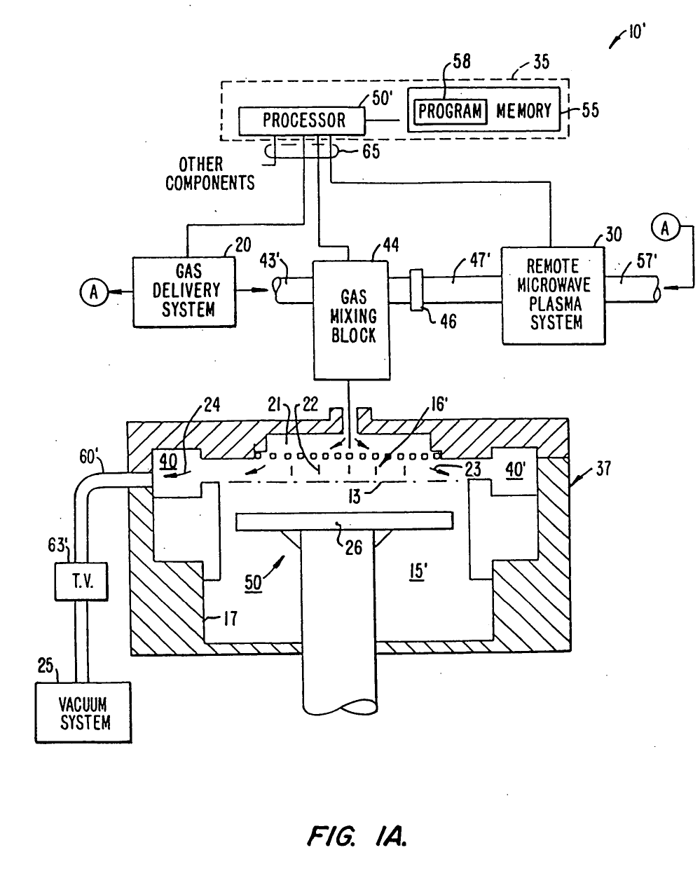

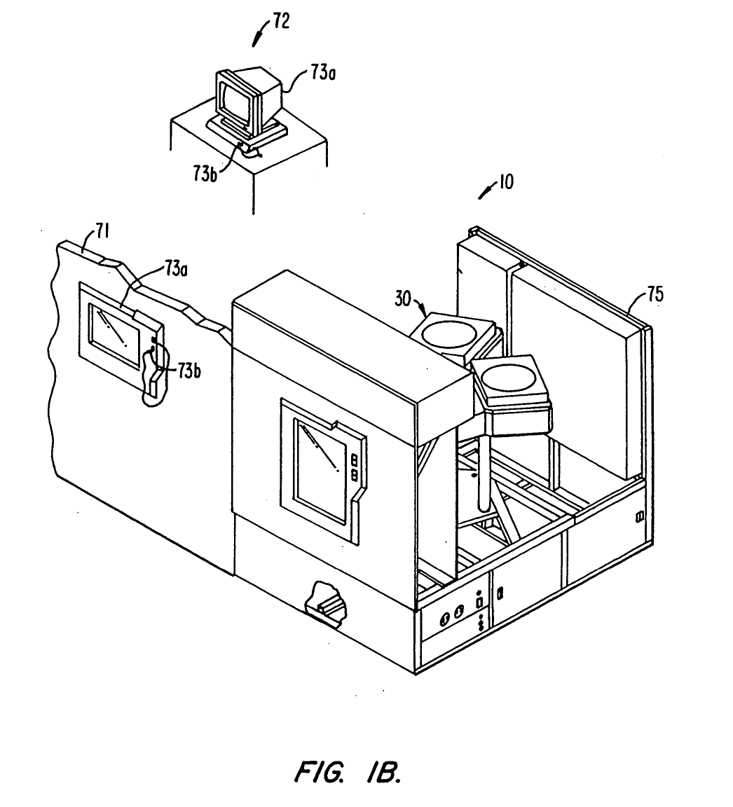

FIG. 1A is a simplified diagram of an exemplary chemical vapor deposition (“CVD”) system 10 in which the method of the present invention can be practiced. This system is suitable for performing thermal, sub-atmospheric CVD (“SACVD”) processes, as well as other processes, such as reflow, drive-in, cleaning, etching, and gettering processes. Multiple-step processes can also be performed on a single substrate or wafer without removing the substrate from the chamber. The major components of the system include, among others, a vacuum chamber 15 that receives process and other gases from a gas delivery system 20, a vacuum system 25, a remote plasma system 30, and a control system 35. These and other components are described in more detail below.

CVD apparatus 10 includes an enclosure assembly 37 that forms vacuum chamber 15 with a gas reaction area 16. A gas distribution plate 21 disperses reactive gases and other gases, such as purge gases, through perforated holes toward a wafer (not shown) that rests on a vertically movable heater 26 (also referred to as a wafer support pedestal). Between gas distribution plate 21 and the wafer is gas reaction area 16. Heater 26 can be controllably moved between a lower position, where a wafer can be loaded or unloaded, for example, and a processing position closely adjacent to the gas distribution plate 21, indicated by a dashed line 13, or to other positions for other purposes, such as for an etch or cleaning process. A center board (not shown) includes sensors for providing information on wafer position.

Heater 26 includes an electrically resistive heating element (not shown) enclosed in a ceramic. The ceramic protects the heating element from potentially corrosive chamber environments and allows the heater to attain temperatures up to about 800° C. In an exemplary embodiment, all surfaces of heater 26 exposed to vacuum chamber 15 are made of a ceramic material, such as aluminum oxide (Al₂O₃ or alumina) or aluminum nitride.

Reactive and carrier gases are supplied from gas delivery system 20 through supply lines 43 into a gas mixing box (also called a gas mixing block) 44, where they are mixed together and delivered to gas distribution plate 21. Gas delivery system 20 includes a variety of gas sources and appropriate supply lines to deliver a selected amount of each source to chamber 15 as would be understood by a person of skill in the art. Generally, supply lines for each of the gases include shut-off valves that can be used to automatically or manually shut-off the flow of the gas into its associated line, and mass flow controllers or other types of controllers that measure the flow of gas or liquid through the supply lines. Depending on the process run by system 10, some of the sources may actually be liquid sources, such as tetraethylorthosilane (“TEOS”), triethylborate (“TEB”) and/or triethylphosphate (“TEPO”), rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art. Gas delivery system may also include an ozone generator to generate ozone from a supply of molecular oxygen when ozone is required by a process run on system 10.

Gas mixing box 44 is a dual input mixing block coupled to process gas supply lines 43 and to a cleaning/etch gas conduit 47. A valve 46 operates to admit or seal gas or plasma from gas conduit 47 to gas mixing block 44. Gas conduit 47 receives gases from an integral remote microwave plasma system 30, which has an inlet 57 for receiving input gases. During deposition processing, gas supplied to the plate 21 is vented toward the wafer surface (as indicated by arrows 23), where it may be uniformly distributed radially across the wafer surface in a laminar flow.

Purging gas may be delivered into the vacuum chamber 15 from gas distribution plate 21 and/or from inlet ports or tubes (not shown) through the bottom wall of enclosure assembly 37. Purge gas introduced from the bottom of chamber 15 flows upward from the inlet port past the heater 26 and to an annular pumping channel 40. Vacuum system 25 which includes a vacuum pump (not shown), exhausts the gas (as indicated by arrows 24) through an exhaust line 60. The rate at which exhaust gases and entrained particles are drawn from annular pumping channel 40 through exhaust line 60 is controlled by throttle valve 63.

Remote microwave plasma system 30 can produce a plasma for selected applications, such as chamber cleaning or etching native oxide or residue from a process wafer. Plasma species produced in the remote plasma system 30 from precursors supplied via the input line 57 are sent via the conduit 47 for dispersion through gas distribution plate 20 to vacuum chamber 15. Remote microwave plasma system 30 is integrally located and mounted below chamber 15 with conduit 47 coming up alongside the chamber to gate valve 46 and gas mixing box 44, which is located above chamber 15. Precursor gases for a cleaning application may include fluorine, chlorine and/or other reactive elements. Remote microwave plasma system 30 may also be adapted to deposit CVD films flowing appropriate deposition precursor gases into remote microwave plasma system 30 during deposition.

The temperature of the walls of deposition chamber 15 and surrounding structures, such as the exhaust passageway, may be further controlled by circulating a heat-exchange liquid through channels (not shown) in the walls of the chamber. The heat-exchanger liquid can be used to heat or cool the chamber walls depending on the desired effect. For example, hot liquid may help maintain an even thermal gradient during a thermal deposition process, whereas a cool liquid may be used to remove heat from the system during an in-situ plasma process, or to limit formation of deposition products on the walls of the chamber. Gas distribution manifold 21 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

System controller 35 controls activities and operating parameters of the deposition system. System controller 35 includes a computer processor 50 and a computer-readable memory 55 coupled to processor 50. Processor 50 executes system control software, such as a computer program 58 stored in memory 70. Memory 70 is preferably a hard disk drive but may be other kinds of memory, such as read-only memory or flash memory. System controller 35 also includes a floppy disk drive (not shown).

Processor 50 operates according to system control software (program 58), which includes computer instructions that dictate the timing, mixture of gases, chamber pressure, chamber temperature, microwave power levels, pedestal position, and other parameters of a particular process. Control of these and other parameters is effected over control lines 65, only some of which are shown in FIG. 1A, that communicatively couple system controller 35 to the heater, throttle valve, remote plasma system and the various valves and mass flow controllers associated with gas delivery system 20.

Processor 50 has a card rack (not shown) that contains a single-board computer, analog and digital input/output boards, interface boards and stepper motor controller boards. Various parts of the CVD system 10 conform to the Versa Modular European (VME) standard which defines board, card cage, and connector dimensions and types. The VME standard also defines the bus structure having a 16-bit data bus and 24-bit address bus.

FIG. 1B is a simplified diagram of a user interface that can be used to monitor and control the operation of CVD system 10. As shown in FIG. 1B, CVD system 10 may be one chamber of a multichamber substrate processing system. In such a multichamber system wafers may be transferred from one chamber to another via a computer controlled robot for additional processing. In some cases the wafers are transferred under vacuum or a selected gas. The interface between a user and system controller 35 is a CRT monitor 73a and a light pen 73b. A mainframe unit 75 provides electrical, plumbing, and other support functions for the CVD apparatus 10. Exemplary multichamber system mainframe units compatible with the illustrative embodiment of the CVD apparatus are currently commercially available as the Precision 5000.TM. and the Centura 5200.TM. systems from APPLIED MATERIALS, INC. of Santa Clara, Calif.

In the preferred embodiment two monitors 73a are used, one mounted in the clean room wall 71 for the operators, and the other behind the wall 72 for the service technicians. Both monitors 73a simultaneously display the same information, but only one light pen 73b is enabled. The light pen 73b detects light emitted by the CRT display with a light sensor in the tip of the pen. To select a particular screen or function, the operator touches a designated area of the display screen and pushes the button on the pen 73b. The touched area changes its highlighted color, or a new menu or screen is displayed, confirming communication between the light pen and the display screen. As a person of ordinary skill would readily understand, other input devices, such as a keyboard, mouse, or other pointing or communication device, may be used instead of or in addition to the light pen 73b to allow the user to communicate with the processor.

FIG. 1C is a block diagram of one embodiment of the hierarchical control structure of the system control software, computer program 58, for the exemplary CVD apparatus of FIG. 1A. Processes such as those for depositing a film, performing a dry chamber clean, or performing reflow or drive-in operations can be implemented under the control of computer program 58 that is executed by processor 50. The computer program code can be written in any conventional computer readable programming language, such as 68000 assembly language, C, C++, Pascal, Fortran, or other language. Suitable program code is entered into a single file, or multiple files, using a conventional text editor and is stored or embodied in a computer-usable medium, such as the system memory.

If the entered code text is in a high-level language, the code is compiled, and the resultant compiler code is then linked with an object code of precompiled WINDOWS™ library routines. To execute the linked compiled object code, the system user invokes the object code, causing the computer system to load the code in memory, from which the CPU reads and executes the code to configure the apparatus to perform the tasks identified in the program.

A user enters a process set number and process chamber number into a process selector subroutine 80 by using the light pen to select a choice provided by menus or screens displayed on the CRT monitor. The process sets, which are predetermined sets of process parameters necessary to carry out specified processes, are identified by predefined set numbers. The process selector subroutine 80 identifies (i) the desired process chamber, and (ii) the desired set of process parameters needed to operate the process chamber for performing the desired process. The process parameters for performing a specific process relate to process conditions such as, for example, process gas composition and flow rates, pedestal temperature, chamber wall temperature pressure and plasma conditions such as magnetron power levels and chamber wall temperature. The process selector subroutine 80 controls what type of process (e.g. deposition, wafer cleaning, chamber cleaning, chamber gettering, reflowing) is performed at a certain time in the chamber. In some embodiments, there may be more than one process selector subroutine. The process parameters are provided to the user in the form of a recipe and may be entered utilizing the light pen/CRT monitor interface.

A process sequencer subroutine 82 has program code for accepting the identified process chamber and process parameters from the process selector subroutine 80, and for controlling the operation of the various process chambers. Multiple users can enter process set numbers and process chamber numbers, or a single user can enter multiple process set numbers and process chamber numbers, so process sequencer subroutine 82 operates to schedule the selected processes in the desired sequence. Preferably, process sequencer subroutine 82 includes program code to perform the steps of (i) monitoring the operation of the process chambers to determine if the chambers are being used, (ii) determining what processes are being carried out in the chambers being used, and (iii) executing the desired process based on availability of a process chamber and the type of process to be carried out.

Conventional methods of monitoring the process chambers, such as polling methods, can be used. When scheduling which process is to be executed, process sequencer subroutine 82 can be designed to take into consideration the present condition of the process chamber being used in comparison with the desired process conditions for a selected process, or the “age” of each particular user-entered request, or any other relevant factor a system programmer desires to include for determining scheduling priorities.

Once process sequencer subroutine 82 determines which process chamber and process set combination is going to be executed next, process sequencer subroutine 82 initiates execution of the process set by passing the particular process set parameters to a chamber manager subroutine 85 which controls multiple processing tasks in a particular process chamber according to the process set determined by process sequencer subroutine 82. For example, chamber manager subroutine 85 has program code for controlling CVD and cleaning process operations in chamber 15. Chamber manager subroutine 85 also controls execution of various chamber component subroutines which control operation of the chamber components necessary to carry out the selected process set. Examples of chamber component subroutines are substrate positioning subroutine 90, process gas control subroutine 91, pressure control subroutine 92, heater control subroutine 93 and remote plasma control subroutine 94. Depending on the specific configuration of the CVD chamber, some embodiments include all of the above subroutines, while other embodiments may include only some of the subroutines or other subroutines not described. Those having ordinary skill in the art would readily recognize that other chamber control subroutines can be included depending on what processes are to be performed in the process chamber. In multichamber systems, additional chamber manager subroutines 86, 87 control activities of other chambers.

In operation, the chamber manager subroutine 85 selectively schedules or calls the process component subroutines in accordance with the particular process set being executed. Chamber manager subroutine 85 schedules the process component subroutines much like the process sequencer subroutine 82 schedules which process chamber and process set are to be executed next. Typically, chamber manager subroutine 85 includes steps of monitoring the various chamber components, determining which components need to be operated based on the process parameters for the process set to be executed, and initiating execution of a chamber component subroutine responsive to the monitoring and determining steps.

Operation of particular chamber component subroutines will now be described with reference to FIGS. 1A and 1C. The substrate positioning subroutine 90 comprises program code for controlling chamber components that are used to load the substrate onto the heater 26 and, optionally, to lift the substrate to a desired height in the chamber to control the spacing between the substrate and the gas distribution manifold 21. When a substrate is loaded into the process chamber 15, the heater 26 is lowered to receive the substrate and then the heater 26 is raised to the desired height. In operation, the substrate positioning subroutine 90 controls movement of the heater 26 in response to process set parameters related to the support height that are transferred from the chamber manager subroutine 85.

Process gas control subroutine 91 has program code for controlling process gas composition and flow rates. Process gas control subroutine 91 controls the state of safety shut-off valves, and also ramps the mass flow controllers up or down to obtain the desired gas flow rate. Typically, process gas control subroutine 91 operates by opening the gas supply lines and repeatedly (i) reading the necessary mass flow controllers, (ii) comparing the readings to the desired flow rates received from the chamber manager subroutine 157a, and (iii) adjusting the flow rates of the gas supply lines as necessary. Furthermore, process gas control subroutine 91 includes steps for monitoring the gas flow rates for unsafe rates, and activating the safety shut-off valves when an unsafe condition is detected. Alternative embodiments could have more than one process gas control subroutine, each subroutine controlling a specific type of process or specific sets of gas lines.

In some processes, an inert gas, such as nitrogen or argon, is flowed into the chamber to stabilize the pressure in the chamber before reactive process gases are introduced. For these processes, process gas control subroutine 91 is programmed to include steps for flowing the inert gas into the chamber for an amount of time necessary to stabilize the pressure in the chamber, and then the steps described above would be carried out. Additionally, when a process gas is to be vaporized from a liquid precursor, such as TEOS, TEPO, or TEB, process gas control subroutine 91 is written to include steps for bubbling a delivery gas such as helium through the liquid precursor in a bubbler assembly, or controlling a liquid injection system to spray or squirt liquid into a stream of carrier gas, such as helium. When a bubbler is used for this type of process, process gas control subroutine 91 regulates the flow of the delivery gas, the pressure in the bubbler, and the bubbler temperature in order to obtain the desired process gas flow rates. As discussed above, the desired process gas flow rates are transferred to process gas control subroutine 91 as process parameters.

Furthermore, process gas control subroutine 91 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The pressure control subroutine 92 includes program code for controlling the pressure in the chamber by regulating the aperture size of the throttle valve in the exhaust system of the chamber. The aperture size of the throttle valve is set to control the chamber pressure at a desired level in relation to the total process gas flow, the size of the process chamber, and the pumping set-point pressure for the exhaust system. When the pressure control subroutine 92 is invoked, the desired or target pressure level is received as a parameter from the chamber manager subroutine 85. Pressure control subroutine 92 measures the pressure in the chamber by reading one or more conventional pressure manometers connected to the chamber, compares the measure value(s) to the target pressure, obtains proportional, integral, and differential (“PID”) values corresponding to the target pressure from a stored pressure table, and adjusts the throttle valve according to the PID values. Alternatively, the pressure control subroutine 92 can be written to open or close the throttle valve to a particular aperture size, i.e. a fixed position, to regulate the pressure in the chamber. Controlling the exhaust capacity in this way does not invoke the feedback control feature of the pressure control subroutine 92.

Heater control subroutine 93 includes program code for controlling the current to a heating unit that is used to heat the substrate. Heater control subroutine 93 is also invoked by the chamber manager subroutine 85 and receives a target, or set-point, temperature parameter. Heater control subroutine 93 measures the temperature by measuring voltage output of a thermocouple located in the heater, comparing the measured temperature to the set-point temperature, and increasing or decreasing current applied to the heating unit to obtain the set-point temperature. The temperature is obtained from the measured voltage by looking up the corresponding temperature in a stored conversion table, or by calculating the temperature using a fourth-order polynomial. Heater control subroutine 93 includes the ability to gradually control a ramp up or down of the heater temperature. This feature helps to reduce thermal cracking in the ceramic heater. Additionally, a built-in fail-safe mode can be included to detect process safety compliance, and can shut down operation of the heating unit if the process chamber is not properly set up.

Remote plasma control subroutine 94 includes program code to control the operation of remote plasma system 30. Plasma control subroutine 94 is invoked by chamber manager 85 in a manner similar to the other subroutines just described.

Although the invention is described herein as being implemented in software and executed upon a general purpose computer, those of skill in the art will realize that the invention could be implemented using hardware such as an application specific integrated circuit (ASIC) or other hardware circuitry. As such, it should be understood that the invention can be implemented, in whole or in part, is software, hardware or both. Those skilled in the art will also realize that it would be a matter of routine skill to select an appropriate computer system to control CVD system 10.

Variations other than those specifically described above will be apparent to persons of skill in the art. These equivalents and alternatives are included within the scope of the present invention. Therefore, the scope of this invention is not limited to the embodiments described, but is defined by the following claims and their full scope of equivalents.

1. A gap-fill method comprising:
disposing in a semiconductor processing chamber a semiconductor workpiece comprising a recessed feature;
causing a first reaction in the processing chamber to deposit a first oxide layer within the first recessed feature at a pressure below 1 ATM, without applying RF energy to generate a plasma within the processing chamber; and
causing a second reaction to deposit a second oxide layer within the recess over the first oxide layer, by applying RF energy to generate a plasma.

2. The method of claim 1 wherein RF energy is applied to the processing chamber to generate a plasma to cause deposition of the second oxide layer.

3. The method of claim 1 wherein the workpiece bearing the first deposited oxide layer is transferred to a second processing chamber, and the RF energy is applied to the second processing chamber to cause deposition of the second oxide layer.

4. The method of claim 1 wherein a remotely-generated reactive ion species is flowed into the processing chamber during formation of the first oxide layer.

5. The method of claim 4 wherein the reactive ion species comprises a fluorinated ion formed by application of RF energy to a remote gas selected from the group consisting of F₂, NF₃, C₂F₆, and C₃F₈.

6. The method of claim 4 wherein the reactive ion species is formed in a remote chamber for generating a plasma to clean the processing chamber.

7. The method of claim 1 wherein the first oxide layer is annealed prior to formation of the second oxide layer.

8. The method of claim 1 wherein the first oxide layer is formed by a deposition/etch/deposition process.

9. The method of claim 1 wherein the second oxide layer is formed by a deposition/etch/deposition process.

10. The method of claim 1 wherein the first oxide layer is deposited over an initial oxide layer formed within the recessed feature utilizing a high density plasma deposition process.

11. The method of claim 1 wherein the semiconductor workpiece disposed within the processing chamber features a recess comprising a trench formed in a surface of the substrate.

12. The method of claim 1 wherein the semiconductor workpiece disposed within the processing chamber features a recess comprising topography formed by structures fabricated on a surface of the substrate.

13. A method of forming silicon oxide comprising:
disposing a semiconductor workpiece comprising a recessed feature in a processing chamber at a pressure below 1 ATM;
mixing an oxygen-containing gas with a silicon-containing precursor gas in the processing chamber to cause a reaction to deposit a silicon oxide layer within the recessed feature without applying RF energy to the processing chamber;
disposing a gas into a remote plasma chamber;
applying RF energy to the remote plasma chamber to generate a reactive ion species; and
flowing the reactive ion species into the processing chamber during mixing of the oxygen containing gas and the silicon-containing precursor gas.

14. The method of claim 13 wherein the gas flowed into the remote plasma chamber comprises a fluorine-containing gas, and the reactive ion species comprises a fluorine-containing ion.

15. The method of claim 14 wherein the fluorine-containing gas is selected from the group consisting of F₂, NF₃, C₂F₆, and C₃F₈.

16. The method of claim 14 further comprising:
causing a reaction to deposit a second oxide layer within the recess over the first oxide layer, by applying RF energy to the processing chamber to generate a plasma.

17. The method of claim 14 wherein the remote plasma chamber is for generating a plasma to clean the processing chamber.

18. A gap-fill method comprising:
disposing in a semiconductor processing chamber a semiconductor workpiece comprising a recessed feature;
causing a first reaction in the processing chamber to deposit a first oxide layer within the first recessed feature at a pressure below 1 ATM, without applying RF energy to generate a plasma within the processing chamber; and
causing a second reaction to deposit a second oxide layer within the recess over the first oxide layer, by applying thermal energy to a silicon-containing precursor in the absence of a plasma.

19. The method of claim 18 wherein applying thermal energy comprises heating the silicon-containing precursor to a temperature of between about 600-1000° C.

20. The method of claim 18 wherein thermal energy is applied to the silicon precursor in the presence of an oxygen-containing gas other than ozone.
